(19) United States
(12) Patent Application Publication
(10) Pub. No.: US 2025/0119078 A1
(43) Pub. Date: Apr. 10, 2025

(54) LAMINATE AND ELECTROSTATIC CHUCK DEVICE

(71) Applicant: Tomoegawa Corporation, Tokyo (JP)

(72) Inventors: Takahito Uemura, Shizuoka-shi (JP); Daigo Andou, Shizuoka-shi (JP)

(21) Appl. No.: 18/836,023

(22) PCT Filed: Jan. 6, 2023
(86) PCT No.: PCT/JP2023/000191

§ 371 Date: Aug. 6, 2024

(30) Foreign Application Priority Data
Feb. 8, 2022 (JP) 2022-017948

(51) Int. Cl. H02N 13/00

(52) U.S. Cl. CPC H02N 13/00

(57) ABSTRACT

The purpose of the present invention is to provide a laminate coated with a ceramic layer and an electrostatic chuck device, wherein the ceramic layer can be detached without damaging any member other than the ceramic layer. The present invention provides a laminate formed by stacking a member, an intermediate layer (50), and a ceramic layer (60), in which the intermediate layer (50) is a water-soluble resin containing ceramic particles, and an electrostatic chuck device (1) formed by stacking a base (10), insulating organic films (41, 42), an intermediate layer (50) and a ceramic layer (60), in which the intermediate layer (50) is a water-soluble resin containing ceramic particles.

### TECHNICAL FIELD

The present invention relates to a laminate and an electrostatic chuck device in which, in a laminate in which is laminated a ceramic layer used in plasma processing processes for manufacturing semiconductors, magnetic disks, magnetic heads, and similar items, the ceramic layer can be easily removed from the laminate.

### BACKGROUND ART

In a thin-film forming apparatus that forms a thin film by depositing particles flown from an evaporation source or target on a film forming part such as a semiconductor wafer, it has been proposed to pre-form, on a portion other than the film forming part such as an inner wall of the apparatus, a metal spray coating such as molybdenum before the particles are deposited and retained to keep the particles adhered and retained (see, for example, Patent Document 1). It has also been proposed to use ceramic coatings such as alumina, aluminum nitride, and Aron ceramic instead of the metal spray coating (see, for example, Patent Document 2).

It has also been proposed to form a ceramic layer on the top surface in an electrostatic chuck device used for manufacturing semiconductor wafers and liquid crystal panels (see, for example, Patent Document 3).

Conventionally, laminates with these ceramic films or ceramic layers (hereinafter collectively referred to as “ceramic layers”) were used in plasma treatment processes, so the ceramic layers deteriorated due to the plasma after prolonged use, leading to the entire laminate being disposed of as waste.

In recent years, to reduce such waste, only the deteriorated ceramic layer is removed from the laminate and the laminate portions other than the ceramic layer are reused.

The ceramic layer is removed from the laminate by etching with a chemical cleaning agent, blasting, or other methods.

### CITATION LIST

### Patent Document

### Patent Document 1

Japanese Unexamined Patent Application, First Publication No. 560-120515

### Patent Document 2

Japanese Unexamined Patent Application, First Publication No. H08-69970

### Patent Document 3

Re-publication of PCT International Publication No. WO2008/053934

### SUMMARY OF THE INVENTION

### Problems to be Solved

Among the conventional methods of stripping the ceramic layer as described above, in the blasting process, simultaneously with the ceramic layer, other components that make up the laminate are removed. In the method of removing the ceramic layer with a chemical cleaning solution, other components of the laminate are deformed or thinned, making it difficult to reuse the laminate.

In addition, in processes such as blast treatment or chemical cleaning solution treatment, the work becomes cumbersome and it is difficult to easily detach the ceramic layer.

The object of the present invention is to provide a laminate coated with a ceramic layer and an electrostatic chuck device, wherein the ceramic layer can be detached without damaging any member other than the ceramic layer.

### Solution to Problem

In view of the current situation described above, as a result of careful study it was found that if a specific intermediate layer is formed on the lower layer of a ceramic layer, the intermediate layer dissolves by water penetrating the ceramic layer, and so the ceramic layer (thermally sprayed layer) can be easily detached without damaging the ceramic layer and other members in the laminated body except for the intermediate layer.

In other words, the present invention has the following aspects:
[1]A laminate formed by stacking a member, an intermediate layer, and a ceramic layer, wherein the intermediate layer is a water-soluble resin containing ceramic particles.
[2] The laminate described in [1], wherein the ceramic particles are alumina particles.
[3] The laminate described in [1] or [2] above, wherein the intermediate layer is 2 to 10 parts by mass of the water-soluble resin per 100 parts by mass of the ceramic particles.
[4] An electrostatic chuck device formed by stacking a base, an insulating organic film, an intermediate layer, and a ceramic layer, wherein the intermediate layer is a water-soluble resin containing ceramic particles.
[5] The electrostatic chuck device as described in [4], wherein the ceramic particles are alumina particles.
[6] The electrostatic chuck device as described in [4] or [5], wherein the intermediate layer is 2 to 10 parts by mass of the water-soluble resin per 100 parts by mass of the ceramic particles.

### Effects of the Invention

The present invention can provide a laminate coated with a ceramic layer and an electrostatic chuck device in which, by immersing the laminate in water, the ceramic layer can be detached without damaging other components other than the ceramic layer.

### BRIEF DESCRIPTION OF DRAWINGS

FIG. 1 is a cross-sectional view showing a schematic configuration of the electrostatic chuck device of the present invention along the height direction of the electrostatic chuck device.

### DESCRIPTION OF EMBODIMENTS

The present invention is described in detail below.

The laminate of the present invention is a laminate consisting of a member, an intermediate layer, and a ceramic layer, wherein the intermediate layer is a water-soluble resin containing ceramic particles.

In the present invention, the member is those used in thin film formation (PVD, CVD) and plasma treatment processes (etching, pre-cleaning, and ashing), with examples including a deposition preventive plate, chamber, bell jar, ring material, and base of an electrostatic chuck device, and example of the materials of those members includes metal, quartz glass, ceramics, and resin.

The intermediate layer contains ceramic particles and water-soluble resin.

There is no particular limitation with respect to the ceramic particles.

Shapes of the ceramic particles include, for example, spherical, perfectly spherical, amorphous, needle-like, fibrous, and plate-like. One of these shapes of ceramic particles may be used alone or in combination of two or more.

Ceramic particle materials include, for example, ceramic particles composed mainly of oxide-based ceramics, non-oxide-based ceramics, and their composite ceramics.

Examples of oxide-based ceramics include alumina (aluminum oxide, Al₂O₃), zirconia (zirconium oxide, ZrO₂), yttria (yttrium oxide, Y₂O₃), talc (hydrous magnesium silicate, Mg₃Si₄O₁₀ (OH)₁₀), hematite (iron(III) oxide, Fe₂O₃), chromia (chromium(III) oxide, Cr₂O₃), titania (titanium dioxide, TiO₂), magnesia (magnesium oxide, MgO), silica (silicon dioxide, SiO₂), calcia (calcium oxide, CaO), ceria (cerium dioxide, CeO₂), tin oxide (SnO₂), zinc oxide (ZnO), steatite (magnesium silicate, MgO—SiO₂), cordierite (2MgO·2Al₂O₃·5SiO₂), mullite (3Al₂O₃·2SiO₂), ferrite (MnFe₂O₄), spinel (MgAl₂O₄), zircon (zirconium silicate, ZrSiO₄), barium titanate (BaTiO₃), lead titanate (PbTiO₃), forsterite (Mg₂SiO₄), phosphorus-doped tin oxide (PTO), antimony-doped tin oxide (ATO), tin-doped indium oxide (ITO), and the like.

Oxide-based ceramics can be used either individually or in combination with two or more types.

Non-oxide-based ceramics include, for example, nitride ceramics, carbide ceramics, boride ceramics, silicide ceramics, and phosphate compounds.

Nitride ceramics include boron nitride (BN), titanium nitride (TiN), silicon nitride (Si₃N₄), gallium nitride (GaN), aluminum nitride (AlN), carbon nitride (CN_{X}), sialon (Si₃N₄—AlN—Al₂O₃ solid solution) and others.

Examples of carbide ceramics include tungsten carbide (WC), chromium carbide (CrC), vanadium carbide (VC), niobium carbide (NbC), molybdenum carbide (MoC), tantalum carbide (TaC), titanium carbide (TiC), zirconium carbide (ZrC), hafnium carbide (HfC), silicon carbide (SiC), and boron carbide (B₄C).

Boride ceramics include, for example, molybdenum boride (MoB), chromium boride (CrB₂), hafnium boride (HfB₂), zirconium boride (ZrB₂), tantalum boride (TaB₂), titanium boride (TiB₂) and the like.

Silicide-based ceramics include, for example, zirconium oxide silicate, hafnium oxide silicate, titanium oxide silicate, lanthanum oxide silicate, yttrium oxide silicate, titanium oxide silicate, tantalum oxide silicate, tantalum nitride silicate and the like.

Examples of phosphate compounds include hydroxyapatite, calcium phosphate and the like.

One non-oxide-based ceramic may be used alone or in combination of two or more.

The ceramic particles are preferably at least one selected from the group consisting of alumina, magnesia, yttria, zirconia, silica, and zinc oxide.

Ceramic particles need only consist mainly of the ceramic materials described above, and may contain other components to the extent that they do not impair the effects of the present embodiment. Ceramic particles may, for example, contain 80% by mass or more of the ceramic materials mentioned above, and may also contain metals such as Fe, Cr, and C as other components.

The average diameter of the primary ceramic particles is preferably 0.1 to 10 μm, and more preferably 1 to 5 μm.

The adoption of the above average particle diameter is based on the laser diffraction and scattering method, and the estimated 50% particle diameter (D50) in the volume-based particle size distribution measured using a commercially available laser diffraction and scattering particle size distribution measuring device can be adopted.

Water-soluble resins include polyacrylamide, polyvinylpyrrolidone, polyalkylene glycol, polyvinyl alcohol, polyethyleneimine, carboxymethylcellulose, and others. Resins obtained by copolymerizing hydrophobic monomers with hydrophilic monomers, such as styrene-acrylic acid copolymers, are particularly preferred. Such resins are preferred because their water solubility can be controlled by changing the ratio of hydrophobic to hydrophilic monomers or by changing their structure (random, grafted, block, etc.).

In the intermediate layer, 2 to 10 parts by mass of water-soluble resin per 100 parts by mass of ceramic particles is preferred, and more preferably 3 to 7 parts by mass. When the water-soluble resin is less than 2 parts by mass, the intermediate layer is difficult to adhere to the member, and when it is more than 10 parts by mass, the ceramic layer is difficult to adhere to the intermediate layer.

The ceramic layer can be obtained by spraying at least one type of ceramic particles, which are oxide-based ceramics, non-oxide-based ceramics, or composite ceramics composed of these, as listed above.

Spraying methods for forming ceramic layers include atmospheric plasma spraying, reduced pressure plasma spraying, water plasma spraying, high-speed flame spraying, gas flame spraying, and explosive spraying. The plasma spray method, which uses electrical energy as a heat source, utilizes sources such as argon, hydrogen, and nitrogen to generate plasma for film formation, and due to the high temperature of the heat source and the fast deposition rate, it is particularly suitable for densely depositing high-melting-point materials, making it suitable for forming ceramic layers.

If the ceramic layer is formed by spraying, the powder for spraying may consist of primary particles of the ceramic particles or secondary particles made by agglomerating multiple primary particles of the ceramic particles. The average particle size of secondary particles is preferably 10 to 100 μm, and more preferably 10 to 50 μm. The shape of the secondary particles should be approximately spherical in order to allow each particle constituting the thermal spraying powder to impact the member at a nearly uniform velocity.

The adoption of the aforementioned average particle diameter is based on the laser diffraction and scattering method, and the estimated 50% particle diameter (D50) in the volume-based particle size distribution measured using a commercially available laser diffraction and scattering particle size distribution measuring device can be adopted.

In the present invention, a laminate constituted by an intermediate layer with water-soluble resin containing ceramic particles is immersed in water at a temperature of 20° C. to 100° C., whereby the water permeates through the ceramic layer and reaches the intermediate layer, dissolves the intermediate layer, and the ceramic layer detaches. The higher the temperature, the shorter the time required for exfoliation, but 1 to 50 hours of immersion in water is preferred. The water for soaking is preferably subjected to ultrasonic vibration.

It is preferable to dry the water present on the laminate after the ceramic layer is detached by the above method, and then remove the remaining ceramic layer with a cleaning tool or the like. Then, after applying the intermediate layer, the ceramic layer can be formed again by thermal spraying or other means.

Next, the electrostatic chuck device of the present invention shall be described in detail.

In the drawings used in the following explanations, the dimensional proportions, etc. of each component may not be the same as in reality.

The present embodiment is described specifically to give a better understanding of the purpose of the invention and is not intended to limit the present invention unless otherwise specified.

### [Electrostatic Chuck Device]

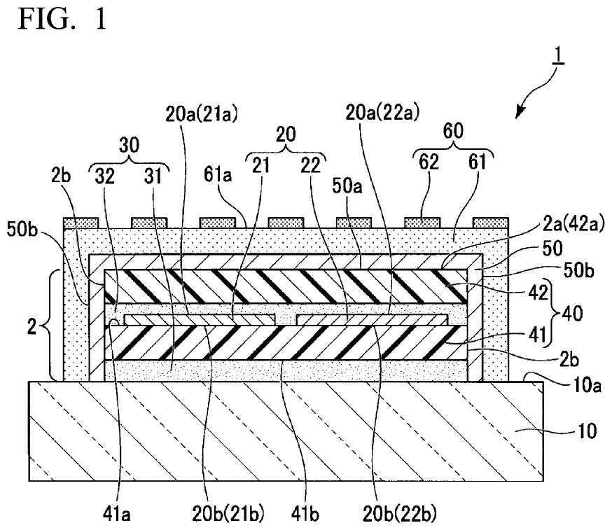

FIG. 1 is a cross-sectional view showing a schematic configuration of the electrostatic chuck device of the present embodiment along the height direction of the electrostatic chuck device.

As shown in FIG. 1, the electrostatic chuck device 1 is provided with a base 10, a plurality of internal electrodes 20, an adhesive layer 30, an insulating organic film 40, an intermediate layer 50, and a ceramic layer 60. In detail, as shown in FIG. 1, the electrostatic chuck device 1 in the present embodiment has the base 10, a first internal electrode 21, a second internal electrode 22, a first adhesive layer 31, a second adhesive layer 32, a first insulating organic film 41, a second insulating organic film 42, the intermediate layer 50, and the ceramic layer 60.

In the electrostatic chuck device 1 of the present embodiment, on the surface 10a of the base 10 (top surface in the direction of the thickness of the base 10), the first adhesive layer 31, the first insulating organic film 41, the first internal electrode 21 and the second internal electrode 22, the second adhesive layer 32, the second insulating organic film 42, the intermediate layer 50, and the ceramic layer 60 are laminated in this order.

The insulating organic film 40 is provided on both sides of the internal electrodes 20 in the thickness direction (top surface 20a of the internal electrode 20 in the thickness direction and bottom surface 20b of the internal electrode 20 in the thickness direction), respectively. In detail, the second insulating organic film 42 is provided on the top surface 21a side of the first internal electrode 21 in the thickness direction and on the top surface 22a side of the second internal electrode 22 in the thickness direction. The first insulating organic film 41 is provided on the bottom surface 21b side of the first internal electrode 21 in the thickness direction and on the bottom surface 22b side of the second internal electrode 22 in the thickness direction.

The first adhesive layer 31 is provided on the surface of the first insulating organic film 41 on the opposite side of the internal electrodes 20 (the bottom surface 41b of the first insulating organic film 41). The second adhesive layer 32 is provided between the first insulating organic film 41 and internal electrodes 20 provided on the top surface 41a of the first insulating organic film 41 in the thickness direction, and the second insulating organic film 42.

The sum of the thickness of the first adhesive layer 31, the thickness of the first insulating organic film 41, the thickness of the internal electrodes 20, the thickness of the second adhesive layer 32, the thickness of the second insulating organic film 42, the thickness of the intermediate layer 50, and the thickness of the ceramic layer 60 (ceramic base layer 61, ceramic surface layer 62) (hereinafter referred to as the “total thickness (1)”) is preferably equal to or less than 200 μm, and more preferably equal to or less than 170 μm. If the total thickness (1) described above is 200 μm or less, the electrostatic chuck device 1 has excellent voltage resistance characteristics and plasma resistance, resulting in excellent adsorption force.

The sum of the thickness of the first adhesive layer 31, the thickness of the first insulating organic film 41, the thickness of the internal electrodes 20, the thickness of the second adhesive layer 32, and the thickness of the second insulating organic film 42 (hereinafter referred to as the “total thickness (2)”) is preferably equal to or less than 110 μm, and more preferably equal to or less than 90 μm. If the total thickness (2) described above is 110 μm or less, the electrostatic chuck device 1 has excellent voltage resistance characteristics and plasma resistance, resulting in excellent adsorption force.

The sum of the thickness of the second adhesive layer 32 and the thickness of the second insulating organic film 42 (hereinafter referred to as the “total thickness (3)”) is preferably 50 μm or less, and more preferably 40 μm or less. If the total thickness (3) described above is 50 μm or less, the electrostatic chuck device 1 has excellent voltage resistance characteristics and plasma resistance, resulting in excellent adsorption force.

The ceramic layer 60 is laminated via the intermediate layer 50 on the top surface 2a (top surface 42a of the second insulating organic film 42) of a laminate film 2 in the thickness direction, including at least the internal electrodes 20 and the insulating organic film 40.

As shown in FIG. 1, the ceramic layer 60 preferably covers all surfaces of the outer surface 2b of the laminate film 2 via the intermediate layer 50 (the top surface 2a and each side surface 2b (the surface along the thickness direction of the laminate film 2, the side surface of the first adhesive layer 31, the side surface of the second adhesive layer 32, the side surface of the first insulating organic film 41, and the side surface of the second insulating organic film 42) of the laminate film 2). In other words, the intermediate layer 50 preferably covers the entire outer surface of the laminate film 2, and the ceramic layer 60 preferably covers the entire outer surface of the intermediate layer 50 (the top surface 50a and all side surfaces 50b (surfaces along the thickness direction of the laminate film 2) of the intermediate layer 50).

As shown in FIG. 1, the ceramic layer 60 preferably has a ceramic base layer 61 and a ceramic surface layer 62 formed on the top surface 61a of the ceramic base layer 61 (top surface in the thickness direction of the ceramic base layer 61) and having unevenness.

The sum of the thickness of the ceramic base layer 61, the thickness of the ceramic surface layer 62, the thickness of the intermediate layer 50, the thickness of the second adhesive layer 32, and the thickness of the second insulating organic film 42 (hereinafter referred to as the “total thickness (4)”) is preferably 125 μm or less, and preferably 110 μm or less. If the total thickness (4) described above is 125 μm or less, the electrostatic chuck device 1 has excellent voltage resistance characteristics and plasma resistance, resulting in excellent adsorption force.

The first internal electrode 21 and the second internal electrode 22 may be in contact with the first insulating organic film 41 or the second insulating organic film 42. The first internal electrode 21 and the second internal electrode 22 may be formed inside the second adhesive layer 32, as shown in FIG. 1. The arrangement of the first internal electrode 21 and the second internal electrode 22 can be designed accordingly.

Since the first internal electrode 21 and the second internal electrode 22 are independent of each other, not only can voltages of the same polarity be applied, but also voltages of different polarity can be applied. The electrode patterns and shapes of the first internal electrode 21 and the second internal electrode 22 are not limited as long as they can adsorb bodies to be adsorbed such as conductors, semiconductors and insulators. Only the first internal electrode 21 may be provided as a single pole.

The electrostatic chuck device 1 of the present embodiment is not limited in terms of other layer configurations as long as the ceramic layer 60 is laminated at least on the top surface 42a of the second insulating organic film 42 via the intermediate layer 50.

While not particularly limited, examples of the base 10 include a ceramic base, a silicon carbide base, and metal base made of materials such as aluminum or stainless steel.

The internal electrodes 20 are not limited to those made of conductive materials that can develop electrostatic adsorption force when voltage is applied. For example, thin films consisting of metals such as copper, aluminum, gold, silver, platinum, chromium, nickel, tungsten, and thin films consisting of at least two metals selected from the aforementioned metals are suitable for the internal electrodes 20. Examples of such thin metal films include those formed by vapor deposition, plating, sputtering, and the like, as well as those formed by applying and drying conductive paste; with specific examples including metal foil such as copper foil.

The thickness of the internal electrodes 20 is not particularly limited as long as the thickness of the second adhesive layer 32 is greater than the thickness of the internal electrode 20. The thickness of the internal electrodes 20 is preferably equal to or less than 20 μm. If the thickness of the internal electrodes 20 is equal to or less than 20 μm, when forming the second insulating organic film 42, it is less likely for unevenness to occur in the top surface 42a thereof. As a result, defects are less likely to occur when forming the ceramic layer 60 on the second insulating organic film 42 or when polishing the ceramic layer 60.

The thickness of the internal electrodes 20 is preferably equal to or greater than 1 μm. If the thickness of the internal electrodes 20 is 1 μm or more, sufficient bonding strength can be obtained when bonding the internal electrode 20 to the first insulating organic film 41 or the second insulating organic film 42.

When voltages of different polarity are applied to the first internal electrode 21 and the second internal electrode 22, the distance between the adjacent first internal electrode 21 and the second internal electrode 22 (the distance in the direction perpendicular to the thickness direction of the internal electrodes 20) is preferably equal to or less than 2 mm. If the distance between the first internal electrode 21 and the second internal electrode 22 is equal to or less than 2 mm, sufficient electrostatic force is generated between the first internal electrode 21 and the second internal electrode 22 to generate sufficient adsorption force.

The distance from the internal electrodes 20 to the body to be adsorbed, i.e., from the top surface 21a of the first internal electrode 21 and the top surface 22a of the second internal electrode 22 to the adsorbed body to be adsorbed on the ceramic surface layer 62 (the total thickness of the second adhesive layer 32, the second insulating organic film 42, the intermediate layer 50, the ceramic base layer 61 and the ceramic surface layer 62 that exist on the top surface 21a of the first internal electrode 21 and the top surface 22a of the second internal electrode 22) is preferably 50 μm to 125 μm. If the distance from the internal electrodes 20 to the body to be adsorbed is 50 μm or more, the insulation of the laminate consisting of the second adhesive layer 32, the second insulating organic film 42, the intermediate layer 50, the ceramic base layer 61 and the ceramic surface layer 62 can be ensured. On the other hand, if the distance from the internal electrodes 20 to the body to be adsorbed is 125 μm or less, sufficient adsorption force is generated.

As an adhesive constituting the adhesive layer 30, an adhesive mainly consisting of one or more resins selected from epoxy resin, phenol resin, styrene block copolymer, polyamide resin, acrylonitrile-butadiene copolymer, polyester resin, polyimide resin, silicone resin, amine compounds, bismaleimide compounds, and the like is used.

Examples of epoxy resins include bisphenol epoxy resin, phenolic novolac epoxy resin, cresol novolac epoxy resin, glycidyl ether epoxy resin, glycidyl ester epoxy resin, glycidylamine epoxy resin, trihydroxyphenyl methane epoxy resin, tetraglycidylphenolalkane epoxy resin, naphthalene epoxy resin, diglycidyl diphenylmethane epoxy resin, diglycidyl biphenyl epoxy resin, and other bifunctional or multifunctional epoxy resins. Among these, bisphenol epoxy resin is preferred. Among bisphenol epoxy resins, bisphenol A epoxy resin is particularly preferred. When an epoxy resin is the main ingredient, curing agents and curing accelerators for epoxy resins such as imidazoles, tertiary amines, phenols, dicyandiamides, aromatic diamines, and organic peroxides can be added as needed.

Phenolic resins include alkyl phenolic resins, p-phenyl phenolic resins, novolac phenolic resins such as bisphenol A phenolic resins, resol phenolic resins, and polyphenyl paraphenolic resins.

Examples of styrene block copolymers include styrene-butadiene-styrene block copolymer (SBS), styrene-isoprene-styrene block copolymer (SIS), and styrene—ethylene-propylene-styrene copolymer (SEPS), among others.

The thickness of the adhesive layer 30 (first adhesive layer 31, second adhesive layer 32) is not particularly limited, but is preferably from 5 μm to 20 m, and more preferably from 10 μm to 20 μm. If the thickness of the adhesive layer 30 (first adhesive layer 31, second adhesive layer 32) is 5 μm or more, it will function adequately as an adhesive. On the other hand, if the thickness of the adhesive layer 30 (first adhesive layer 31 and second adhesive layer 32) is 20 μm or less, the inter-electrode insulation of the internal electrodes 20 can be secured without compromising the adsorption force.

The materials that make up the insulating organic film 40 are not particularly limited, and for example polyester such as polyethylene terephthalate, polyolefin such as polyethylene, polyimide, polyamide, polyamideimide, polyethersulfone, polyphenylene sulfide, polyetherketone, polyetherimide, triacetyl cellulose, silicone rubber, and polytetrafluoroethylene, among others, are used. Among these, polyester, polyolefin, polyimide, silicone rubber, polyetherimide, polyethersulfone, and polytetrafluoroethylene are preferred due to their excellent insulation properties, with polyimide being particularly preferred. As polyimide films, products such as Kapton (brand name by Toray DuPont) and Upilex (brand name by Ube Industries) are used, for example.

The thickness of the insulating organic film 40 (first insulating organic film 41 and second insulating organic film 42) is not particularly limited, but is preferably from 10 μm to 100 μm, and more preferably from 10 μm to 50 μm. If the thickness of the insulating organic film 40 (first insulating organic film 41 and second insulating organic film 42) is 10 μm or more, insulation can be ensured. On the other hand, if the thickness of the insulating organic film 40 (first insulating organic film 41 and second insulating organic film 42) is less than 100 μm, sufficient adsorption force is generated.

The intermediate layer 50 contains ceramic particles and water-soluble resin.

There is no particular limitation with respect to the ceramic particles.

Shapes of the ceramic particles include, for example, spherical, perfectly spherical, amorphous, needle-like, fibrous, and plate-like. One of these shapes of ceramic particles may be used alone or in combination of two or more.

Ceramic particle materials include, for example, ceramic particles composed mainly of oxide-based ceramics, non-oxide-based ceramics, and their composite ceramics.

Examples of oxide-based ceramics include alumina (aluminum oxide, Al₂O₃), zirconia (zirconium oxide, ZrO₂), yttria (yttrium oxide, Y₂O₃), talc (hydrous magnesium silicate, Mg₃Si₄O₁₀(OH)₁₀), hematite (iron(III) oxide, Fe₂O₃), chromia (chromium(III) oxide, Cr₂O₃), titania (titanium dioxide, TiO₂), magnesia (magnesium oxide, MgO), silica (silicon dioxide, SiO₂), calcia (calcium oxide, CaO), ceria (cerium dioxide, CeO₂), tin oxide (SnO₂), zinc oxide (ZnO), steatite (magnesium silicate, MgO·SiO₂), cordierite (2MgO·2Al₂O₃·5SiO₂), mullite (3Al₂O₃·2SiO₂), ferrite (MnFe₂O₄), spinel (MgAl₂O₄), zircon (zirconium silicate, ZrSiO₄), barium titanate (BaTiO₃), lead titanate (PbTiO₃), forsterite (Mg₂SiO₄), phosphorus-doped tin oxide (PTO), antimony-doped tin oxide (ATO), tin-doped indium oxide (ITO), and the like.

Oxide-based ceramics can be used either individually or in combination with two or more types.

Non-oxide-based ceramics include, for example, nitride ceramics, carbide ceramics, boride ceramics, silicide ceramics, and phosphate compounds.

Nitride ceramics include boron nitride (BN), titanium nitride (TiN), silicon nitride (Si₃N₄), gallium nitride (GaN), aluminum nitride (AlN), carbon nitride (CN_{X}), sialon (Si₃N₄—AlN—Al₂O₃ solid solution) and others.

Examples of carbide ceramics include tungsten carbide (WC), chromium carbide (CrC), vanadium carbide (VC), niobium carbide (NbC), molybdenum carbide (MoC), tantalum carbide (TaC), titanium carbide (TiC), zirconium carbide (ZrC), hafnium carbide (HfC), silicon carbide (SiC), and boron carbide (B₄C).

Examples of boride ceramics include molybdenum boride (MoB), chromium boride (CrB₂), hafnium boride (HfB₂), zirconium boride (ZrB₂), tantalum boride (TaB₂), and titanium boride (TiB₂).

Examples of silicide-based ceramics include zirconium oxide silicate, hafnium oxide silicate, titanium oxide silicate, lanthanum oxide silicate, yttrium oxide silicate, titanium oxide silicate, tantalum oxide silicate, and tantalum nitride silicate.

Examples of phosphate compounds include hydroxyapatite, calcium phosphate and the like.

One non-oxide-based ceramic may be used alone or in combination of two or more.

The ceramic particles are preferably at least one selected from the group consisting of alumina, magnesia, yttria, zirconia, silica, and zinc oxide.

Ceramic particles need only consist mainly of the ceramic materials described above, and may contain other components to the extent that they do not impair the effects of the present embodiment. Ceramic particles may, for example, contain 80% by mass or more of the ceramic materials mentioned above, and may also contain metals such as Fe, Cr, and C as other components.

The average diameter of the primary ceramic particles is preferably 0.1 to 10 μm, and more preferably 1 to 5 μm.

The adoption of the aforementioned average particle diameter is based on the laser diffraction and scattering method, and the estimated 50% particle diameter (D50) in the volume-based particle size distribution measured using a commercially available laser diffraction and scattering particle size distribution measuring device can be adopted.

Water-soluble resins include polyacrylamide, polyvinylpyrrolidone, polyalkylene glycol, polyvinyl alcohol, polyethyleneimine, carboxymethylcellulose, and others. Resins obtained by copolymerizing hydrophobic monomers with hydrophilic monomers, such as styrene-acrylic acid copolymers, are particularly preferred. Such resins are preferred because their water solubility can be controlled by changing the ratio of hydrophobic to hydrophilic monomers or by changing their structure (random, grafted, block, etc.).

In the intermediate layer 50, 2 to 10 parts by mass of water-soluble resin per 100 parts by mass of ceramic particles is preferred, and more preferably 3 to 7 parts by mass. When the water-soluble resin is less than 2 parts by mass, the intermediate layer 50 is difficult to adhere to the base 10, and when it is more than 10 parts by mass, the ceramic layer 60 is difficult to adhere to the intermediate layer 50.

The thickness of the intermediate layer 50 is preferably between 1 μm and 40 μm, and more preferably between 5 μm and 20 μm. If the thickness of the intermediate layer 50 is 1 μm or thicker, the intermediate layer 50 will not be locally thin, and the ceramic layer 60 can be formed uniformly on the intermediate layer 50 by thermal spraying. On the other hand, if the thickness of the intermediate layer 50 is 40 μm or less, sufficient adsorption force is generated.

As materials constituting the ceramic layer 60, it is possible to list at least one type of ceramic particles from the oxide-based ceramics, non-oxide-based ceramics, and their composite ceramics mentioned above.

The average diameter of the primary ceramic particles is preferably 0.1 to 10 μm, and more preferably 1 to 5 μm.

When the ceramic layer 60 is formed by thermal spraying, the powder for thermal spraying may be secondary particles agglomerated from multiple primary particles of the above ceramic particles. The average particle size of secondary particles is preferably 10 to 100 μm, and more preferably 10 to 50 μm. The shape of the secondary particles should be approximately spherical, or may be elliptically spherical or cylindrical in order to allow each particle constituting the thermal spraying powder to impact the material at a nearly uniform velocity.

The adoption of the aforementioned average particle diameter is based on the laser diffraction and scattering method, and the estimated 50% particle diameter (D50) in the volume-based particle size distribution measured using a commercially available laser diffraction and scattering particle size distribution measuring device can be adopted.

The thickness of the ceramic base layer 61 is preferably between 10 μm and 80 μm, and more preferably between 40 μm and 60 μm. If the thickness of the ceramic base layer 61 is 10 μm or thicker, it exhibits sufficient plasma and voltage resistance. On the other hand, if the thickness of the ceramic base layer 61 is 80 μm or less, sufficient adsorption force is generated.

The thickness of the ceramic surface layer 62 is preferably 5 μm to 20 μm. If the thickness of the ceramic surface layer 62 is 5 μm or thicker, unevenness can be formed over the entire area of the ceramic surface layer 62. On the other hand, if the thickness of the ceramic surface layer 62 is less than 20 μm, sufficient adsorption force is generated.

The ceramic surface layer 62 can be polished to improve its adsorption power, and its surface unevenness can be adjusted as surface roughness Ra.

Here, the surface roughness Ra means the value measured by the method specified in JIS B0601-1994.

The surface roughness Ra of the ceramic surface layer 62 should be between 0.05 μm and 0.5 μm. If the surface roughness Ra of the ceramic surface layer 62 is within the aforementioned range, the body to be adsorbed can be adsorbed well. As the surface roughness Ra of the ceramic surface layer 62 increases, the contact area between the body to be adsorbed and the ceramic surface layer 62 decreases, resulting in a smaller adsorption force.

The electrostatic chuck device 1 of the present embodiment described above is provided with the plurality of internal electrodes 20, the insulating organic film 40 provided on both sides of the internal electrodes 20 in the thickness direction, and a ceramic layer 60 laminated via the intermediate layer 50 on the top surface 2a of the laminate film 2 including at least the internal electrodes 20 and the insulating organic film 40 in the thickness direction. Therefore, at least on the top surface 2a side of the laminate film 2 in the thickness direction, plasma resistance and voltage resistance are improved, and abnormal discharges during use can be suppressed. Therefore, the electrostatic chuck device 1 in the present embodiment also has excellent adsorption properties.

In the electrostatic chuck device 1 of the present embodiment, if the ceramic layer 60 covers the entire outer surface of the laminate film 2 via the intermediate layer 50, the plasma resistance and voltage resistance are improved on the top surface 2a side and side surface 2b sides of the laminate film 2, and abnormal discharge during use can be suppressed. Therefore, the electrostatic chuck device 1 in the present embodiment exhibits even better adsorption capability.

In the electrostatic chuck device 1 of the present embodiment, the ceramic layer 60 has a ceramic base layer 61 and a ceramic surface layer 62 formed on the top surface 61a of the ceramic base layer 61 and having unevenness, which can be controlled to the desired adsorption force.

In the electrostatic chuck device 1 of the present embodiment, the intermediate layer 50 has a water-soluble resin containing ceramic particles, which allows the ceramic layer to be detached by immersing the electrostatic chuck device 1 in water at a temperature of 20° C. to 100° C. The higher the temperature, the shorter the time required for exfoliation, but 1 to 50 hours of immersion in water is preferred. The water for soaking should be subjected to ultrasonic vibration.

In the electrostatic chuck device 1 of the present embodiment, the insulating organic film is a polyimide film, which improves voltage resistance.

### [Method of Manufacturing Electrostatic Chuck]

Referring to FIG. 1, the method of manufacturing the electrostatic chuck device 1 of the present embodiment shall be described.

A thin film of metal, such as copper, is deposited on the surface 41a of the first insulating organic film 41 (top surface of the first insulating organic film 41 in the direction of thickness). Etching is then performed to pattern the thin film of metal into a predetermined shape to form the first internal electrode 21 and the second internal electrode 22.

Next, a second insulating organic film 42 is affixed to the top surface 20a of the internal electrodes 20 via the second adhesive layer 32.

Next, the laminate comprising the first insulating organic film 41, the internal electrodes 20, the second adhesive layer 32, and the second insulating organic film 42 is bonded to the surface 10a of the base 10 via the first adhesive layer 31, so that the bottom surface 41b of the first insulating organic film 41 is on the surface 10a side of the base 10.

Next, the intermediate layer 50 is formed so as to cover the entire outer surface of the laminate film 2 including the internal electrodes 20 and the insulating organic films 40.

The method of forming the intermediate layer 50 is not limited as long as the intermediate layer 50 can be formed to cover the entire outer surface of the laminate film 2. Methods for forming the intermediate layer 50 include, for example, bar coating, spin coating, and spray coating.

Next, the ceramic base layer 61 is formed to cover the entire outer surface of the intermediate layer 50.

Method of forming the ceramic base layer 61 include, for example, applying a slurry containing a material constituting the ceramic base layer 61 to the entire outer surface of the intermediate layer 50 and sintering it to form the ceramic base layer 61, and spraying a material constituting the ceramic base layer 61 onto the entire outer surface of the intermediate layer 50 to form the ceramic base layer 61. Thermal spray methods for forming the ceramic base layer 61 include atmospheric plasma spraying, reduced pressure plasma spraying, water plasma spraying, high-speed flame spraying, gas flame spraying, and explosive spraying. The plasma spray method, which uses electrical energy as a heat source, utilizes sources such as argon, hydrogen, and nitrogen to generate plasma for film formation, and due to the high temperature of the heat source and the fast flame rate, it is particularly suitable for densely depositing high-melting-point materials, making it suitable, as a flame spraying, for forming ceramic layers.

Next, the ceramic surface layer 62 is formed on the top surface 61a of the ceramic base layer 61.

Methods of forming the ceramic surface layer 62 include, for example, a method that forms the ceramic surface layer 62 by depositing the material comprising the ceramic surface layer 62 onto the top surface 61a of the ceramic base layer 61 by thermal spraying after masking the top surface 61a of the ceramic base layer 61 with a predetermined shape, and a method that, after forming the ceramic surface layer 62 by depositing the material that constitutes the ceramic surface layer 62 over the entire top surface 61a of the ceramic base layer 61 by thermal spraying, grinds the ceramic surface layer 62 by blasting to form the ceramic surface layer 62 in an uneven shape.

By the above process, the electrostatic chuck device 1 of this embodiment can be fabricated.

### EXAMPLES

The following examples and comparative examples will further illustrate the invention in detail, but the invention is not limited to the following examples.

### Example 1

As the first insulating organic film 41, a polyimide film with a thickness of 12.5 μm (trade name: Kapton, manufactured by Toray-Dupont) was plated with copper on one side to a thickness of 9 μm. After applying a photoresist to the surface of the copper foil, a pattern exposure was followed by a development process, with unwanted copper foil then removed by etching. The photoresist was then removed by washing the copper foil on the polyimide film to form the first internal electrode 21 and the second internal electrode 22. An insulating adhesive sheet, semi-hardened by drying and heating, was laminated as the second adhesive layer 32 on the first internal electrode 21 and the second internal electrode 22. As the insulating adhesive sheet, a sheet formed by mixing and dissolving 27 parts by mass of bismaleimide resin, 3 parts by mass of diamino siloxane, 20 parts by mass of resole phenolic resin, 10 parts by mass of biphenyl epoxy resin, and 240 parts by mass of ethyl acrylate-butyl acrylate-acrylonitrile copolymer in an appropriate amount of tetrahydrofuran was used. Then, as the second insulating organic film 42, a polyimide film with a thickness of 12.5 μm (trade name: Kapton, manufactured by Toray-Dupont) was affixed to the laminate and bonded by heat treatment. The thickness of the second adhesive layer 32 after drying was 20 μm.

Furthermore, a sheet consisting of an insulating adhesive of the same composition as the aforementioned semi-cured insulating adhesive sheet was laminated as the first adhesive layer 31 on the surface of the first insulating organic film 41 in the laminate on the opposite side of the surface on which the first internal electrode 21 and the second internal electrode 22 were formed. The laminate was then affixed to the aluminum base 10 and bonded by heat treatment. The thickness of the first adhesive layer 31 after drying was 10 μm.

Next, a slurry was prepared by uniformly dispersing 2 parts by mass of polyacrylamide aqueous solution (polyacrylamide content: 6.8% by mass) and 3 parts by mass of amorphous particles composed of alumina (average primary particle size: 3 μm) using an ultrasonic disperser. In the slurry, the amount of polyacrylamide relative to the alumina-based amorphous particles is 4.5 parts by mass.

Next, the slurry was sprayed on the surface of the second insulating organic film 42 of the laminate film 2 adhered to the base 10 and on the sides of the laminate film 2, and then heated and dried to form the intermediate layer 50. Heating and drying were performed at 60° C. for 1 hour, followed by heating at 110° C. for 2 hours. The thickness of the intermediate layer 50 on the surface of the second insulating organic film 42 after the heating and drying was 20 μm.

Next, alumina powder (average primary particle size: 8 μm) was sprayed on all surfaces of the aforementioned intermediate layer 50 to form a 30 μm thick ceramic base layer 61 by plasma spraying.

Then, after masking the surface of the ceramic base layer 61 with a predetermined shape, the above alumina powder (average primary particle size: 8 μm) was sprayed onto the surface of the ceramic base layer 61 to form a 15 μm thick ceramic surface layer 62.

Next, the adsorption surface of the ceramic surface layer 62, which adsorbs the body to be adsorbed, was ground flat with a diamond wheel to obtain the electrostatic chuck device of Example 1.

The surface of the obtained electrostatic chuck device was measured according to JIS B0601-1994, and the surface roughness Ra was 0.3 μm.

Next, the electrostatic chuck device obtained in Example 1 above was used to evaluate the following characteristics, such as voltage resistance, adsorption force, and plasma resistance.

### (Voltage Resistance)

The voltage resistance characteristic was evaluated by applying a voltage of ±2.5 kV to the first internal electrode 21 and the second internal electrode 22 from a high-voltage power supply device to the electrostatic chuck device under vacuum (10 Pa) and holding the device for 2 minutes. After visual observation for 2 minutes, the electrostatic chuck device obtained in Example 1 showed no change and exhibited a good voltage resistance characteristic.

### (Adsorption Force)

The adsorption force was evaluated by using a silicone dummy wafer as the body to be adsorbed, causing it to be adsorbed to the surface of the electrostatic chuck device under vacuum (10 Pa or less), applying a voltage of 2.5 kV to the first internal electrode 21 and the second internal electrode 22, and holding it for 30 seconds. Helium gas flowed through a through-hole in the base 10 while the voltage was applied, and the amount of helium gas leakage was measured while increasing the gas pressure. The electrostatic chuck device obtained in Example 1 was able to stably adsorb the dummy wafer at a good gas pressure of 100 Torr.

### (Plasma Resistance)

Plasma resistance was evaluated by installing the electrostatic chuck device in a parallel plate type RIE (Reactive Ion Etching) apparatus, and then, under vacuum conditions (20 Pa or less) and with a high-frequency power supply (output 250 W), introducing oxygen gas (10 sccm) and carbon tetrafluoride gas (40 sccm), and observing changes in the surface condition of the electrostatic chuck device after 24 hours of exposure. The electrostatic chuck device obtained in Example 1 had good plasma resistance with the ceramic layer remaining on the entire surface.

After the evaluation described above, the electrostatic chuck device obtained in Example 1 was immersed in water for 24 hours. After 24 hours, the electrostatic chuck device was removed from the water and an attempt was made to detach the thermally sprayed ceramic layer, which came off to expose the surface of the insulating organic film 42.

Next, the entire electrostatic chuck device with the ceramic layer detached was dried and the remaining ceramic layer was removed with a cleaning tool. The exposed insulating organic film 42 surface could again be provided with the intermediate layer 50, and the reapplied intermediate layer 50 was well adhered to the insulating organic film 42 surface. Then, alumina powder (average primary particle size: 8 μm) was thermally sprayed on all surfaces. The thermally sprayed ceramic spray coating was well adhered to the intermediate layer 50.

### Example 2

The electrostatic chuck device of Example 2 was obtained in a similar manner except for substituting the aforementioned slurry with one composed of 2 parts by weight of polyacrylamide aqueous solution (polyacrylamide content: 6.8% by mass) and 2 parts by weight of amorphous particles composed of alumina (average primary particle diameter: 3 μm). In the slurry, the amount of polyacrylamide relative to the alumina-based amorphous particles is 6.8 parts by mass.

Next, as in Example 1 above, the voltage resistance characteristic, adsorption force, and plasma resistance of the electrostatic chuck device in Example 2 were evaluated. The results showed good results in all of the voltage resistance characteristic, adsorption force, and plasma resistance.

The electrostatic chuck device obtained in Example 2 of the above evaluation was immersed in water for 24 hours. After 24 hours, the electrostatic chuck device was removed from the water and an attempt was made to detach the thermally sprayed ceramic layer, which came off to expose the surface of the insulating organic film 42.

Next, the entire electrostatic chuck device with the ceramic layer detached was dried and the remaining ceramic layer was removed with a cleaning tool. The exposed insulating organic film 42 surface could again be provided with the intermediate layer 50, and the reapplied intermediate layer 50 was well adhered to the insulating organic film 42 surface. Then, alumina powder (average primary particle size: 8 μm) was thermally sprayed on all surfaces. The thermally sprayed ceramic spray coating was well adhered to the intermediate layer 50.

### Example 3

The electrostatic chuck device of Example 3 was obtained in a similar manner except for substituting the aforementioned slurry with one composed of 1 part by weight of polyacrylamide aqueous solution (polyacrylamide content: 6.8% by mass) and 4 parts by weight of spherical particles composed of alumina (average primary particle diameter: 4.9 μmφ). In the slurry, the amount of polyacrylamide relative to the alumina-based spherical particles is 1.7 parts by mass.

Next, as in Example 1 above, the voltage resistance characteristic, adsorption force, and plasma resistance of the electrostatic chuck device in Example 3 were evaluated. The results showed good results in all of the voltage resistance characteristic, adsorption force, and plasma resistance.

The electrostatic chuck device obtained in Example 3 of the above evaluation was immersed in water for 24 hours. After 24 hours, the electrostatic chuck device was removed from the water and an attempt was made to detach the thermally sprayed ceramic layer, which came off to expose the surface of the insulating organic film 42.

Next, the entire electrostatic chuck device with the ceramic layer detached was dried and the remaining ceramic layer was removed with a cleaning tool. Next, the exposed insulating organic film 42 surface could again be provided with the intermediate layer 50, and the reapplied intermediate layer 50 was well adhered to the insulating organic film 42 surface. Then, alumina powder (average primary particle size: 8 μm) was thermally sprayed on all surfaces. The thermally sprayed ceramic spray coating was well adhered to the intermediate layer 50.

### INDUSTRIAL APPLICABILITY

In the laminate coated with the ceramic layer of the present invention, the ceramic layer can be detached by immersion in water without damaging other components of the laminate. Such a laminate is beneficial for use in an electrostatic chuck device.

### REFERENCE SIGNS LIST

1 Electrostatic chuck device
2 Laminate film
10 Base
20 Internal electrode
21 First internal electrode
22 Second internal electrode
30 Adhesive layer
31 First adhesive layer
32 Second adhesive layer
40 Insulating organic film
41 First insulating organic film
42 Second insulating organic film
50 Intermediate layer
60 Ceramic layer
61 Ceramic base layer
62 Ceramic surface layer

1. A laminate formed by stacking a member, an intermediate layer, and a ceramic layer, wherein the intermediate layer is a water-soluble resin containing ceramic particles.

2. The laminate according to claim 1, wherein the ceramic particles are alumina particles.

3. The laminate according to claim 1, wherein the intermediate layer is 2 to 10 parts by mass of the water-soluble resin per 100 parts by mass of the ceramic particles.

4. An electrostatic chuck device formed by stacking a base, an insulating organic film, an intermediate layer, and a ceramic layer, wherein the intermediate layer is a water-soluble resin containing ceramic particles.

5. The electrostatic chuck device according to claim 4, wherein the ceramic particles are alumina particles.

6. The electrostatic chuck device according to claim 4, wherein the intermediate layer is 2 to 10 parts by mass of the water-soluble resin per 100 parts by mass of the ceramic particles.
